(19) United States
(12) Patent Application Publication
(10) Pub. No.: US 2023/0245862 A1
(43) Pub. Date: Aug. 3, 2023

(54) DELIVERY OF HIGH CONCENTRATIONS OF MOLECULAR HYDROGEN AND OTHER GASES TO SUBSTRATE PROCESSING SYSTEMS

(71) Applicant: LAM RESEARCH CORPORATION, Fremont, CA (US)

(72) Inventors: Anthony John RICCI, Redwood City, CA (US); Ramon Liwanag BUAN, Santa Clara, CA (US); Wayne Edward RICHTER, San Jose, CA (US); Christopher J. PENA, Hayward, CA (US); Marissa Elena Ortiz AMAYA, San Jose, CA (US)

(21) Appl. No.: 18/013,347

(22) PCT Filed: Jun. 15, 2022
(86) PCT No.: PCT/US2022/033516

§ 371 Date: Dec. 28, 2022

Related U.S. Application Data
(60) Provisional application No. 63/211,224, filed on Jun. 16, 2021.

(51) Int. Cl. H01J 37/32

(52) U.S. Cl. CPC H01J 37/32449; H01J 37/32834; H01J 37/32899; H01J 37/32357; H01J 2237/182; H01J 2237/186; H01J 2237/334; H01J 2237/24585

(57) ABSTRACT

A gas delivery system for substrate processing tool includes a first gas box configured to supply a first gas mixture including one or more gases selected from a first set of N gases to a first substrate processing chamber, where N is an integer greater than one. A second gas box is configured to selectively supply a second gas mixture including one or more gases selected from a second set of M gases to a second substrate processing chamber, where M is an integer greater than one. A third gas box is configured to supply a third gas to the first substrate processing chamber at a first concentration and to supply the third gas to the second substrate processing chamber at a second concentration. The third gas is incompatible with one or more gases in the first set of N gases and with one or more gas in the second set of M gases.

### CROSS-REFERENCE TO RELATED APPLICATIONS

This application claims the benefit of U.S. Provisional Application No. 63/211,224, filed on Jun. 16, 2021. The entire disclosure of the application referenced above is incorporated herein by reference.

### FIELD

The present disclosure relates to substrate processing systems, and more particularly to gas delivery systems of substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. Example processes that may be performed on a substrate include, but are not limited to, chemical vapor deposition (CVD), atomic layer deposition (ALD), dielectric etch, conductor etch, and/or other etch, deposition, stripping or cleaning processes. A substrate may be arranged on a substrate support, such as a pedestal, an electrostatic chuck (ESC), etc. in a processing chamber of the substrate processing system. During stripping and etching, gas mixtures including one or more precursors may be introduced into the processing chamber and plasma may be used to initiate chemical reactions.

### SUMMARY

A gas delivery system for substrate processing tool includes a first gas box configured to supply a first gas mixture including one or more gases selected from a first set of N gases to a first substrate processing chamber, where N is an integer greater than one. A second gas box is configured to selectively supply a second gas mixture including one or more gases selected from a second set of M gases to a second substrate processing chamber, where M is an integer greater than one. A third gas box is configured to supply a third gas to the first substrate processing chamber at a first concentration and to supply the third gas to the second substrate processing chamber at a second concentration.

In other features, the third gas is incompatible with one or more gases in the first set of N gases and with one or more gas in the second set of M gases. The one or more gases in the first set of N gases includes molecular oxygen. The one or more gases in the second set of M gases includes molecular oxygen. The third gas includes molecular hydrogen. Third gas includes ammonia. The first concentration of the third gas is greater than 4%. The first concentration of the third gas is in a range from 4% to 100%. The second concentration of the third gas is greater than 4%. The second concentration of the third gas is in a range from 4% to 100%.

In other features, an interlock circuit is configured to selectively prevent delivery of the one or more gases in the first set of N gases to the first substrate processing chamber at the same time that the third gas is delivered to the first substrate processing chamber. The interlock circuit is further configured to selectively prevent delivery of the third gas when a chamber interlock signal is asserted. The interlock circuit is further configured to selectively prevent delivery of the one or more gases in the second set of M gases to the second substrate processing chamber at the same time that the third gas is delivered to the second substrate processing chamber.

In other features, the one or more gases in the first set of N gases includes molecular oxygen. The one or more gases in the second set of M gases includes molecular oxygen. The third gas includes molecular hydrogen. The first concentration of the third gas is greater than 4% and the second concentration of the third gas is greater than 4%.

In other features, an interlock circuit is configured to selectively prevent delivery of the one or more gases in the first set of N gases to the first substrate processing chamber at the same time that the third gas is delivered to the first substrate processing chamber. The interlock circuit is further configured to selectively prevent delivery of the one or more gases in the second set of M gases to the second substrate processing chamber at the same time that the third gas is delivered to the second substrate processing chamber.

In other features, the interlock circuit is further configured to selectively prevent delivery of the third gas when a chamber interlock signal is asserted. The third gas box includes an enclosure that is connected to an exhaust system. A pressure sensor monitors pressure in the enclosure. A controller is configured to assert a fault signal when the pressure is greater than a predetermined pressure.

In other features, a controller is configured to at least one of purge or pump down the first substrate processing chamber for a first predetermined period when switching from the one or more gases in the first set of N gases to the third gas and when switching from the third gas to the one or more gases in the first set of N gases.

A substrate processing tool includes a substrate transfer module and 2P substrate processing chambers, where P is an integer greater than one. The 2P substrate processing chambers are connected to the substrate transfer module. The substrate processing tool further includes the gas delivery system, the first substrate processing chamber and the second substrate processing chamber. The first substrate processing chamber and the second substrate processing chamber are connected to the substrate transfer module.

In other features, P=5. P of the 2P substrate processing chambers are arranged in a first row on one side of the substrate transfer module and P of the 2P substrate processing chambers are arranged in a second row on an opposite side of the substrate transfer module.

In other features, the first substrate processing chamber and the second substrate processing chamber are arranged at one end of the substrate transfer module.

In other features, the 2P substrate processing chambers perform etching of substrates and wherein the first substrate processing chamber and the second substrate processing chamber perform stripping of the substrates.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a perspective view of an example of portions of two tools according to the present disclosure;

FIG. 2 is a top view of an example of a portion of one of the tools of FIG. 1 according to the present disclosure;

FIG. 3 is a functional block diagram of an example of a gas delivery system according to the present disclosure;

FIG. 4A is a functional block diagram of an example of a controller for the gas delivery system according to the present disclosure;

FIG. 4B is a functional block diagram of an interlock circuit according to the present disclosure; and

FIG. 5 is a flowchart of an example of a method for operating the gas delivery system according to the present disclosure.

In the drawings, reference numbers may be reused to identify similar and/or identical elements.

### DETAILED DESCRIPTION

Semiconductor tools are typically arranged in a fabrication (fab) room. Floor space in the fab room is expensive and therefore semiconductor manufacturers attempt to maximize the throughput per unit area. As a result, a significant amount of attention is given to minimizing the footprint of semiconductor tools.

In the foregoing description, a gas delivery system will be described in the context of a semiconductor tool including two adjacent rows each including P processing chambers (where P is an integer greater than one) that face inwardly and are connected to a common substrate transfer module. R processing chambers are arranged at one end of the substrate processing tool and also communicate with the substrate transfer module (where R is an integer greater than zero). In some examples, the P processing chambers perform etching and the R processing chambers perform stripping, although other types of processes may be performed. In some examples, P = 5 and R = 2, although additional or fewer substrate processing chambers can be used.

A gas delivery system according to the present disclosure is configured to deliver a first gas and one or more other gases to the R substrate processing chambers. In some examples, the gas delivery system includes first and second gas boxes that deliver a first set of N gases and a second set of M gases, respectively, where M and N are integers. A third gas box delivers a third gas. In some examples, the first set of N gases and the second set of M gases may include molecular nitrogen (N₂), molecular oxygen (O₂), argon (Ar), forming gas and/or one or more other process gases or inert gases. In some examples, the third gas includes a gas that is incompatible with one or more gases in the first set of N gases or the second set of M gases. For example, the third gas includes molecular hydrogen (H₂), ammonia (NH₃), or other gas.

In some examples, the third gas can be delivered at concentrations from 0% to 100% of the gas mixture. When the third gas is H₂, higher concentrations (e.g. 4% to 100%) may be incompatible with one or more of the first set of N gases or the second set of M gases (such as molecular oxygen O₂) that are capable of being delivered to the processing chamber at the same time. In other words, O₂ is incompatible with higher concentrations of H₂. Normally, delivery of H₂ is limited to a concentration from 0% to 4%, which is compatible with O₂ (such as in forming gas). In some examples, the third gas box can supply the third gas at 10,000 sccm for one or both chambers (e.g. 5000 sccm to both if operated simultaneously), although higher or lower flow rates can be used.

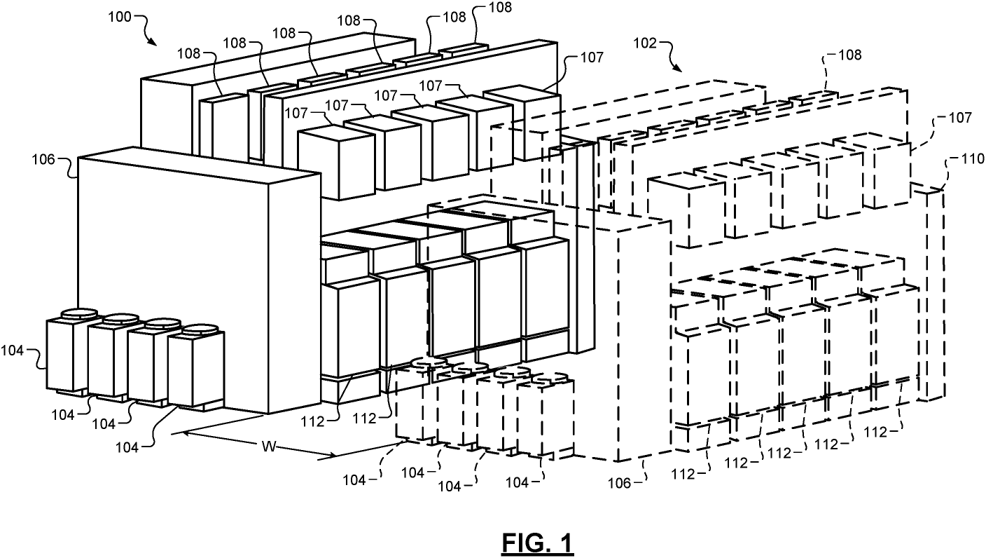

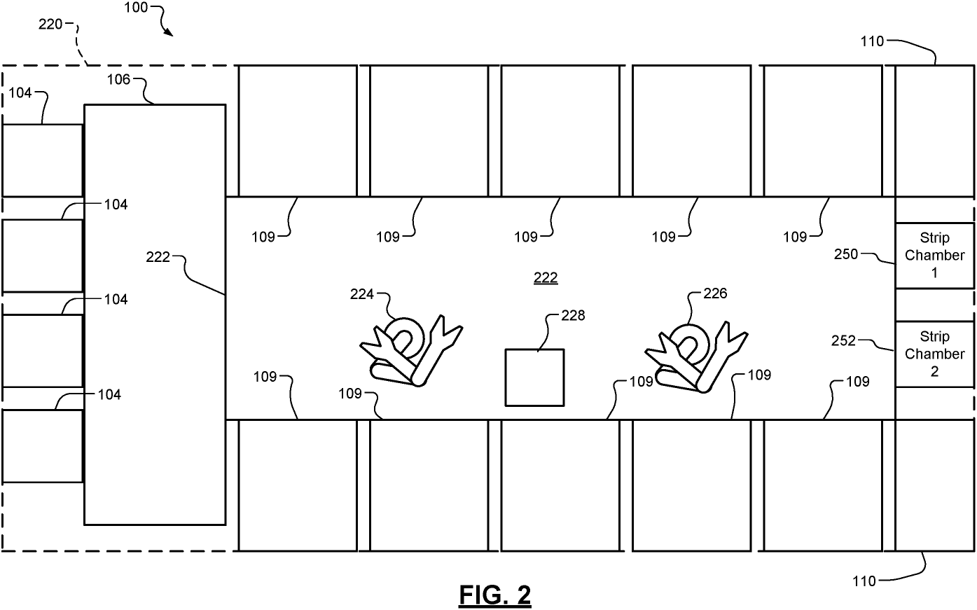

FIGS. 1 and 2 show portions of tools 100, 102 (one in solid lines at 100 and the other in dashed lines at 102) disposed side-by-side in a fab room. Each of tools includes two rows of substrate processing chambers (one row is shown for each of the tools). The substrate processing chambers are located adjacent to a substrate transfer module (not depicted in FIG. 1 for clarity).

The tools 100, 102 include: front opening unified pods (FOUPs) 104; an equipment front end module (EFEM) and load lock 106; processing chambers with radio frequency generators 107 and gas boxes 108; and a power lock out and tag out panel 110. The substrate processing chambers further include process module bias assemblies 112.

Each of the substrate processing chambers may be used to etch substrates using, for example, radio frequency (RF) plasma. The substrate processing chambers may use inductively coupled plasma to perform conductive etch or dielectric etch processes or other substrate treatments.

FIG. 2 shows a plan view of the tool 100. The tool 100 includes the FOUPs 104, the EFEM and load lock 106, the substrate processing chambers 109, and power lock out and tag out panel 110. The tool has an overall footprint identified by dotted lines 220. The tool 100 further includes a substrate transfer module 222 for transferring substrates to and from the substrate processing chambers 109. The substrate transfer module 222 may include robots 224, 226 and a buffer 228 for temporary storage of substrates. The robots 224, 226 transfer substrates to and from the substrate processing chambers 109 and the buffer 228. In some examples, the substrate transfer module 222 operates at vacuum or atmosphere.

The tool 100 further includes first and second substrate processing chambers 250 and 252 located at the same end of the substrate transfer module 222 for performing substrate treatments. In some examples the first and second substrate processing chambers 250 and 252 are strip chambers for performing stripping of film, masks or other material. In some examples, the first and second substrate processing chambers 250 and 252 utilize remote plasma and high concentrations of a gas (such as molecular hydrogen (H₂) above 4%) during stripping of film.

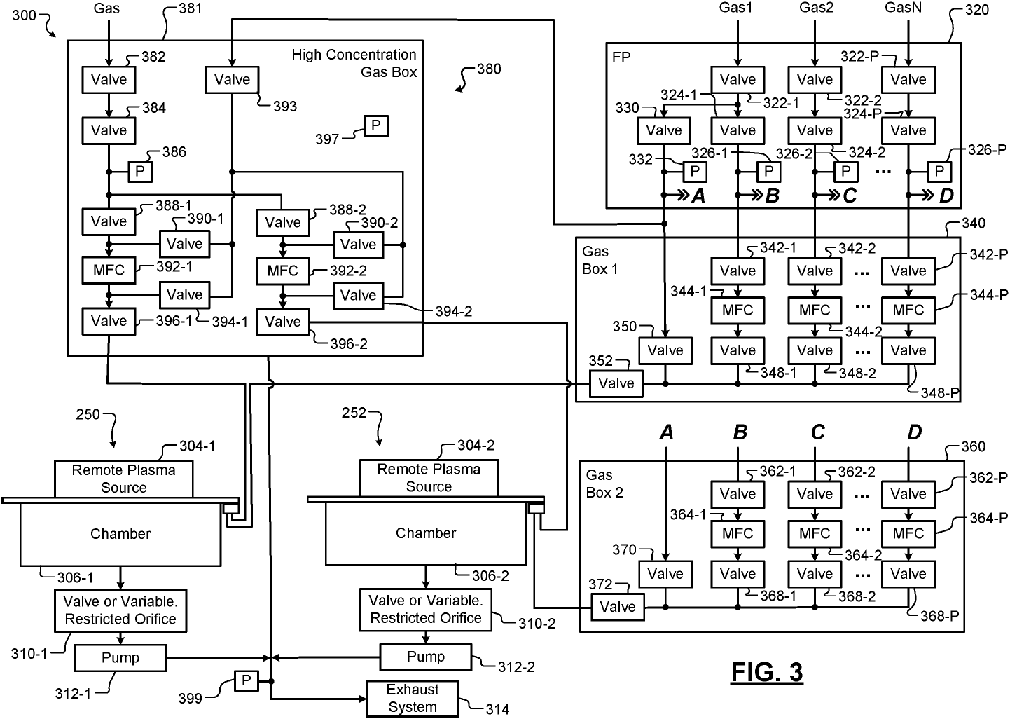

Referring now to FIG. 3, a gas delivery system 300 for the first and second substrate processing chambers 250 and 252 is shown. The gas delivery system 300 supplies gas mixtures to the first substrate processing chamber 250 and a remote plasma source (RPS) 304-1. In some examples, the first substrate processing chamber 250 further includes a chamber enclosure 306-1, a valve or variable restricted orifice 310-1 and a pump 312-1.

In some examples, the gas delivery system 300 also supplies a gas mixture to a second substrate processing chamber 252 and a remote plasma source (RPS) 304-2. In some examples, the second substrate processing chamber 252 further includes a chamber enclosure 306-2, a valve or variable restricted orifice 310-2 and a pump 312-2. While a specific type of chamber is shown, other types of chambers can be used either with or without plasma.

The gas delivery system 300 includes a facilities interface panel (FIP) enclosure 320. N gases including Gas 1, Gas 2, ... and Gas N (where N is an integer) are delivered to the FIP enclosure 320. In some examples, Gas 1 corresponds to molecular nitrogen (N₂) and Gas 2 corresponds to molecular oxygen (O₂). The remaining gases may include other process gases, purge gases, inert gases, etc that are selected based upon the particular process to be performed.

Inlets of valves 322-1, 322-2, ... and 322-N (collectively valves 322) receive the N gases including Gas 1, Gas 2, ... and Gas N and control flow to outlets of the valves 322-1, 322-2, ... and 322-N thereof, respectively. Inlets of valves 324-1, 324-2, ... and 324-N (collectively valves 324) are connected to outlets of the valves 322-1, 322-2, ... and 322-N, respectively. Outlets of the valves 324-1, 324-2, ... and 324-N fluidly communicate with gas boxes 340 and 360 as will be described further below. Pressure sensors 326-1, 326-2, ... and 326-N monitor pressure at the outlets of the valves 324-1, 324-2, ... and 324-N, respectively.

A valve 330 has an inlet that fluidly communicates with an outlet of the valve 322-1 and an inlet of the valve 324-1. An outlet of the valve 330 fluidly communicates with an inlet of a gas box 380. A pressure sensor 332 monitors pressure at the outlets of the valve 330.

The gas box 340 includes valves 342-1, 342-2, ... and 342-N (collectively valves 342) having inlets fluidly communicating with outlets of the valves 324-1, 324-2, ... and 324-N, respectively. Mass flow controllers (MFC) 344-1, 344-2, ... and 344-N communicate with outlets of the valves 342-1, 342-2, ... and 342-N, respectively, to control flow rates of the respective gases. Outlets of the MFCs 344-1, 344-2, ... and 344-N fluidly communicate with inlets of valves 348-1, 348-2, ... and 348-N (collectively valves 348), respectively. An inlet of a valve 350 fluidly communicates with an outlet of the valve 330. Outlets of valves 348-1, 348-2, ... and 348-N and 350 fluidly communicate with an inlet of valve 352. An outlet of the valve 352 fluidly communicates with the first substrate processing chamber 250.

The gas box 360 includes valves 362-1, 362-2, ... and 362-N (collectively valves 362) having inlets fluidly communicating with outlets of the valves 324-1, 324-2, ... and 324-N, respectively. Mass flow controllers (MFC) 364-1, 364-2, ... and 364-N communicate with outlets of the valves 362-1, 362-2, ... and 362-N, respectively, to control flow rates of the respective gases. Outlets of the MFCs 364-1, 364-2, ... and 364-N fluidly communicate with inlets of valves 368-1, 368-2, ... and 368-N (collectively valves 368), respectively. An inlet of a valve 370 fluidly communicates with an outlet of the valve 330. Outlets of valves 368-1, 368-2, ... and 368-N and 370 fluidly communicate with an inlet of valve 372. An outlet of the valve 372 fluidly communicates with the second substrate processing chamber 252.

In some examples, a gas box 380 including an enclosure 381 is configured to supply concentrations of a third gas such as molecular hydrogen (H₂) to one or both of the first substrate processing chamber 250 and the second substrate processing chamber 252. The gas box 380 includes a valve 382 having an inlet receiving the gas. An outlet of the valve 382 communicates with an inlet of a valve 384. An outlet of the valve 384 communicates with an inlet of valve 388-1 and a pressure sensor 386.

An outlet of the valve 388-1 communicates with an inlet of a mass flow controller (MFC) 392-1 that controls a gas flow rate. An outlet of the MFC 392-1 communicates with an inlet of a valve 396-1. An inlet of the valve 393 fluidly communicates with the outlet of the valve 330. An outlet of the valve 393 is connected to inlets of valves 390-1 and 394-1 having outlets fluidly communicating with the inlet and outlet of the MFC 392-1, respectively.

The outlet of the valve 384 also communicates with an inlet of valve 388-2. An outlet of the valve 388-2 communicates with an inlet of a mass flow controller (MFC) 392-2. An outlet of the MFC 392-2 communicates with an inlet of a valve 396-2. The outlet of the valve 393 is fluidly connected to inlets of valves 390-2 and 394-2 having outlets fluidly communicating with the inlet and outlet of the MFC 392-1, respectively. In some examples, the enclosure 381 is a gas sealed enclosure that is connected to an exhaust system 314.

In some examples, Gas 1 corresponds to a purge gas such as molecular nitrogen (N₂). In some situations, gas delivery lines through the gas box 380 are purged using the purge gas by opening the valves 322-1, 330, 393, 390-1, 394-1, 390-2, 394-2 and 396-1. The pumps 312-1 and 312-2 pump the purge gas from the first substrate processing chamber 301-1 and the second substrate processing chamber 252, respectively, to the exhaust system 314. Similarly, the valves 322-1, 330, 350, 352, 370, 372 are opened to purge the lines from the gas boxes 340 and 360, respectively.

In some examples, the gas delivery lines are pumped down and/or purged for a predetermined period when switching from supplying high concentrations of the gas (such as H₂) to supplying another gas (such as O₂). Likewise, the gas delivery lines are pumped down and/or purged for a predetermined period when switching from supplying a gas (such as O₂) to supplying high concentrations of gas (such as H₂).

In some examples, the valves 322 and 362 are manual valves, the valves 330 and 384 are pressure regulating valves, and the remaining valves are solenoid-actuated pneumatic valves, although other types of valves can be used.

In some examples, the enclosure 381 is sealed and pressure inside of the enclosure 381 is monitored by a pressure sensor 397. Alternately, pressure in exhaust lines from the enclosure 381 is monitored by a pressure sensor 399. If the exhaust system is not operating correctly, pressure measured by the pressure sensor 397 and/or the pressure sensor 399 will vary. For example, if the pump 398 fails, the pressure will increase as vacuum is lost. In some examples, the measured pressure can be compared to a predetermined pressure threshold and a fault can be declared when pressure rises above the pressure threshold to prevent leakage of the third gas (such as H₂) supplied by the gas box 380 from the enclosure 381. In some examples, a chamber interlock signal goes low when the pressure increases above the predetermined pressure threshold.

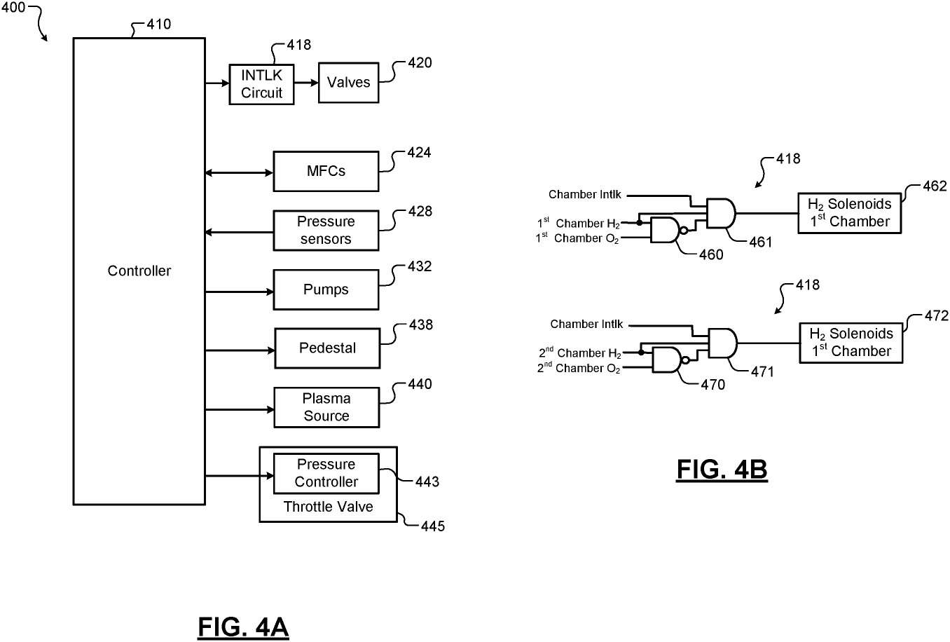

Referring now to FIG. 4A, a control system 400 for the gas delivery system 300 is shown. The control system 400 includes a controller 410 that outputs control signals to an interlock circuit 418 and valve solenoids 420, MFCs 424, and pumps 432 based one or more recipes, processing chamber control code, gas delivery control code and feedback from pressure sensors 428.

In some examples, the interlock circuit 418 prevents the gas box 340 from supplying one or more of the gases at the same time that the gas box 380 is supplying the third gas to the first substrate processing chamber 250 and/or the second substrate processing chamber 252. For example, the interlock circuit 418 is configured to prevent the gas boxes 340 and 360 from delivering a gas (such as O₂) at the same time that the gas box 380 is supplying the third gas (such as H₂) (at any concentration and/or at concentrations greater than predetermined concentrations). A pressure controller 443 may receive outputs of one or more the pressure sensors 428 and modulate a throttle valve 445.

Referring now to FIG. 4B, an example of the interlock circuit 418 is shown. The interlock circuit 418 includes one or more logic gates that prevent supply of the third gas when delivering another gas (such as O₂) at the same time and/or when a chamber interlock is asserted. In some examples, the logic gates include one or more NAND gates 460 and/or AND gates 461.

The NAND gate 460 receives a first signal for enabling supply of a gas (such as O₂) from the gas box 340 to the first substrate processing chamber 250 and a second signal for enabling supply of the third gas (such as H₂) from the gas box 380 to the first substrate processing chamber 250. An output of the NAND gate 460, the second signal and a third signal corresponding to a chamber interlock signal are input to the AND gate 461. The NAND gate 460 is HIGH when one of the two inputs thereto are HIGH and otherwise LOW. The AND gate 461 is high when the output of the NAND gate 460 is HIGH, the second signal is high and the chamber interlock signal is HIGH (corresponding to an enabling condition) and otherwise LOW. An output of the AND gate 461 selectively enables solenoids 462 associated with valves for supplying molecular hydrogen to the first substrate processing chamber 250.

The interlock circuit 418 also includes logic gates performing a similar function for the second substrate processing chamber. In some examples, the logic gates include a NAND gate 470 receiving a fourth signal for enabling supply of O₂ from the gas box 360 to the second substrate processing chamber 252 and a fifth signal for enabling supply of H₂ from the gas box 380 to the second substrate processing chamber 252. The AND gate 471 receives an output of the NAND gate 470, the fifth signal and a sixth signal corresponding to a chamber interlock signal. An output of the AND gate 471 selectively enables solenoids 472 associated with valves for supplying H₂ to the second substrate processing chamber 252.

As can be appreciated, if the first signal and the second signal are asserted at the same time, the NAND gate 460 outputs a disable signal to disable the solenoids 462. In other words, if O₂ is being supplied to the first substrate processing chamber 250, then H₂ is prevented from being supplied to the first substrate processing chamber 250. In addition, the chamber interlock signal can also prevent supply of either H₂ or O₂ when it is LOW.

Likewise, if both the fourth signal and the fifth signal are asserted at the same time, the NAND gate 470 outputs a disable signal to disable the solenoids 472. In other words, if O₂ is being supplied to the second substrate processing chamber 252 or a chamber interlock is asserted, then H₂ is prevented from being supplied to the second substrate processing chamber 252. In addition, the chamber interlock signal can also prevent supply of either H₂ or O₂ when it is LOW.

This type of hardware interlock prevents delivery of incompatible gases and/or gas mixtures to the first substrate processing chamber 250 and the second substrate processing chamber 252, respectively. In addition, software interlocks are also used to prevent delivery of incompatible gases and/or gas mixtures to the first substrate processing chamber 250 and the second substrate processing chamber 252, respectively, as will be described further below.

In some examples, the interlock circuit 418 can be disabled. For example, the interlock circuit 418 can be disabled when the third gas that is used is compatible with the gases supplied by the gas boxes 340 or 360.

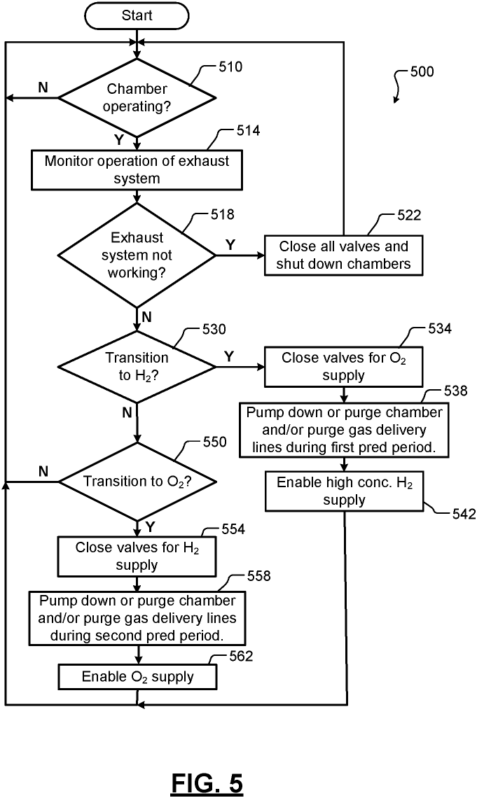

Referring now to FIG. 5, a method 500 for operating the gas delivery system is shown. At 510, the method determines whether the chamber is operating. If 510 is true, the method continues at 514 and monitors operation of the exhaust system. At 518, if the exhaust system is not operating correctly, the processing chambers are shut down. In some examples, the exhaust system pressure and/or pressure in the enclosure 381 is monitored to determine whether or not the exhaust system is operating, although additional or different methods may be used. This step may include one or more of the following: closing all process gas supply valves, optionally perform a purge of the chambers and/or gas lines as described above, and/or shutting power down to other components of the processing chamber.

If 518 is false (the exhaust system is working), the method continues at 530 and determines whether the process needs to transition to supplying the third gas (such as H₂). If 530 is true, the method continues at 534 and closes valves supplying one the first set of N gases and/or one of the second set of M gases of gases (such as O₂) if the valves are open.

At 538, the method pumps down or purges the chamber and/or gas delivery lines for a first predetermined period. In some examples, the first predetermined period can be set within a predetermined range. In some examples, the first predetermined range is between 0 and 300 seconds. At 542, after the first predetermined period, the method enables valves supplying the third gas such as H₂.

If 530 is false, the method continues at 550 and determines whether the process needs to transition to supplying one the first set of N gases and/or one of the second set of M gases of gases (such as O₂). If 550 is true, the method continues at 554 and closes valves supplying the third gas (such as H₂). At 558, the method pumps down or purges the chamber and/or gas delivery lines for a second predetermined period. In some examples, the second predetermined period can be set within a predetermined range. In some examples, the second predetermined range is between 0 and 300 seconds, although other periods can be used. At 562, after the second predetermined period, the method enables valves supplying the third gas such as O₂.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A gas delivery system for substrate processing tool, comprising:
a first gas box configured to supply a first gas mixture including one or more gases selected from a first set of N gases to a first substrate processing chamber, where N is an integer greater than one;
a second gas box configured to selectively supply a second gas mixture including one or more gases selected from a second set of M gases to a second substrate processing chamber, where M is an integer greater than one; and
a third gas box configured to supply a third gas to the first substrate processing chamber at a first concentration and to supply the third gas to the second substrate processing chamber at a second concentration.

2. The gas delivery system of claim 1, wherein the third gas is incompatible with one or more gases in the first set of N gases and with one or more gas in the second set of M gases.

3. The gas delivery system of claim 2, wherein the one or more gases in the first set of N gases includes molecular oxygen.

4. The gas delivery system of claim 3, wherein the one or more gases in the second set of M gases includes molecular oxygen.

5. The gas delivery system of claim 4, wherein the third gas comprises molecular hydrogen.

6. The gas delivery system of claim 3, wherein the third gas comprises ammonia.

7. The gas delivery system of claim 5, wherein the first concentration of the third gas is greater than 4%.

8. The gas delivery system of claim 5, wherein the first concentration of the third gas is in a range from 4% to 100%.

9. The gas delivery system of claim 5, wherein the second concentration of the third gas is greater than 4%.

10. The gas delivery system of claim 5, wherein the second concentration of the third gas is in a range from 4% to 100%.

11. The gas delivery system of claim 1, further comprising an interlock circuit configured to selectively prevent delivery of the one or more gases in the first set of N gases to the first substrate processing chamber at the same time that the third gas is delivered to the first substrate processing chamber.

12. The gas delivery system of claim 11, wherein the interlock circuit is further configured to selectively prevent delivery of the third gas when a chamber interlock signal is asserted.

13. The gas delivery system of claim 11, wherein the interlock circuit is further configured to selectively prevent delivery of the one or more gases in the second set of M gases to the second substrate processing chamber at the same time that the third gas is delivered to the second substrate processing chamber.

14. The gas delivery system of claim 1, wherein:
the one or more gases in the first set of N gases includes molecular oxygen;
the one or more gases in the second set of M gases includes molecular oxygen;
the third gas comprises molecular hydrogen;
the first concentration of the third gas is greater than 4%; and
the second concentration of the third gas is greater than 4%.

15. The gas delivery system of claim 14, further comprising an interlock circuit configured to:
selectively prevent delivery of the one or more gases in the first set of N gases to the first substrate processing chamber at the same time that the third gas is delivered to the first substrate processing chamber; and
selectively prevent delivery of the one or more gases in the second set of M gases to the second substrate processing chamber at the same time that the third gas is delivered to the second substrate processing chamber.

16. The gas delivery system of claim 15, wherein the interlock circuit is further configured to selectively prevent delivery of the third gas when a chamber interlock signal is asserted.

17. The gas delivery system of claim 1, wherein the third gas box includes an enclosure that is connected to an exhaust system.

18. The gas delivery system of claim 17, further comprising a pressure sensor to monitor pressure in the enclosure.

19. The gas delivery system of claim 18, further comprising a controller configured to assert a chamber interlock signal when the pressure is greater than a predetermined pressure.

20. The gas delivery system of claim 1, further comprising a controller configured to at least one of purge or pump down the first substrate processing chamber for a first predetermined period when switching from the one or more gases in the first set of N gases to the third gas and when switching from the third gas to the one or more gases in the first set of N gases.

21. A substrate processing tool comprising:
a substrate transfer module;
2P substrate processing chambers, where P is an integer greater than one,
wherein the 2P substrate processing chambers are connected to the substrate transfer module;
the gas delivery system of claim 1;
the first substrate processing chamber; and
the second substrate processing chamber,
wherein the first substrate processing chamber and the second substrate processing chamber are connected to the substrate transfer module.

22. The substrate processing tool of claim 21, wherein P=5.

23. The substrate processing tool of claim 21, wherein P of the 2P substrate processing chambers are arranged in a first row on one side of the substrate transfer module and P of the 2P substrate processing chambers are arranged in a second row on an opposite side of the substrate transfer module.

24. The substrate processing tool of claim 23, wherein the first substrate processing chamber and the second substrate processing chamber are arranged at one end of the substrate transfer module.

25. The substrate processing tool of claim 24, wherein the 2P substrate processing chambers perform etching of substrates and wherein the first substrate processing chamber and the second substrate processing chamber perform stripping of the substrates.
